(19) United States
(12) Patent Application Publication
(10) Pub. No.: US 2025/0219661 A1
(43) Pub. Date: Jul. 3, 2025

(54) ENCODING PROCESS FOR LDPC CODEWORDS LONGER THAN 1944 BITS

(71) Applicant: NXP USA, Inc., AUSTIN, TX (US)

(72) Inventors: Rui Cao, Sunnyvale, CA (US); Hongyuan Zhang, Fremont, CA (US); Rong Zhang, San Jose, CA (US)

(21) Appl. No.: 18/984,379

(22) Filed: Dec. 17, 2024

Related U.S. Application Data
(60) Provisional application No. 63/615,570, filed on Dec. 28, 2023.
(60) Provisional application No. 63/560,344, filed on Mar. 1, 2024.

(51) Int. Cl. H03M 13/25; H03M 13/11

(52) U.S. Cl. CPC H03M 13/255; H03M 13/11

(57) ABSTRACT

A wireless communication system, apparatus, and methodology are described for encoding Low-Density Parity Check (LDPC) PPDUs by selecting a first LDPC codeword length of N×1944 bits from an encoding parameter table having a plurality of LDPC codeword lengths based on comparing the number of available bits (Navbits) to one or more Navbits threshold values and/or one or more selection conditions for choosing the first LDPC codeword length of N×1944 bits, where N is an integer that is greater than or equal to 2.

### CROSS-REFERENCE TO RELATED APPLICATION AND PRIORITY CLAIM

This application claims the benefit of U.S. Provisional Patent Application No. 63/615,570 entitled “WiFi LDPC Encoding Process for Codeword Longer than 1944” filed Dec. 28, 2023, and U.S. Provisional Patent Application No. 63/560,344 entitled “WiFi LDPC Encoding Process for Codeword Longer than 1944” filed Mar. 1, 2024, each of which is incorporated by reference in its entirety as if fully set forth herein.

### FIELD

The present disclosure is directed in general to communication networks. In one aspect, the present disclosure relates generally to wireless local area network (WLAN) implementing the Institute of Electrical and Electronics Engineers (IEEE) 802.11 standard and any other standards and/or networks that can provide wireless transfer of data.

### DESCRIPTION OF THE RELATED ART

An ever-increasing number of relatively inexpensive, low power wireless data communication services, networks and devices have been made available over the past number of years, promising near wire speed transmission and reliability. Enabling technology advances in the area of wireless communications, various wireless technology standards (including for example, the IEEE Standards 802.11a/b/g, 802.11n, 802.11ac, 802.11ax, and 802.11be and their updates and amendments, as well as the IEEE Standard 802.11bn now in the process of being developed) have been introduced that are known to persons skilled in the art and are collectively incorporated by reference as if set forth fully herein fully. Existing 802.11 standards have improved and expanded wireless data transmission performance and system throughput in applications, such as video teleconferencing, streaming entertainment, high definition (HD) video surveillance applications, outdoor video sharing applications, etc. For example, the 802.11n standard enabled higher data transmission rates by specifying forward error correction (FEC) techniques, such as a low-density parity-check (LDPC) encoding technique wherein data being transmitted is first encoded with LDPC codewords which could have different lengths of 648, 1296 and 1944 bits which could be used with different code rates. While the 802.11n LDPC codes have been the backbone error correction coding scheme for WiFi for over 15 years, the longest LDPC code block length of 1944 bits does not meet the performance requirements of next generation coding schemes which employ MIMO schemes, larger modulation sizes (from 64-QAM to 4096-QAM), and increased bandwidth (from 40 MHz to 320 MHz), along with higher aggregations. There have been proposals to increase the length of LDPC codewords in order to enhance coding gains. To balance the performance and complexity, longer LDPC codewords of length being a multiple of 1944 have been proposed to leverage the design of existing 1944 code. In one example, the new long LDPC code has a length of 2×1944=3888 bits. There are performance vs. complexity vs. hardware cost trade-offs with choosing an encoding procedure for longer LDPC codeword lengths which are non-trivial to solve.

### BRIEF DESCRIPTION OF THE DRAWINGS

The present invention may be understood, and its numerous objects, features and advantages obtained, when the following detailed description of a preferred embodiment is considered in conjunction with the following drawings.

FIG. 1 is a simplified block diagram of a wireless communications system in accordance with selected embodiments of the present disclosure.

FIG. 2 is a simplified block diagram of a multi-link communications system in accordance with selected embodiments of the present disclosure.

FIG. 3 depicts a wireless device in accordance with selected embodiments of the present disclosure.

FIG. 4 depicts a physical layer protocol data unit (PPDU) encoding parameter table specifying a conventional set of LDPC encoding parameters having a maximum LDPC codeword size of 1944 bits in accordance with the IEEE 802.11n standard.

FIG. 5 depicts a PPDU encoding parameter table specifying a first set of LDPC encoding parameters including a Navbits threshold for selecting a maximum LDPC codeword size of N×1944 bits which replaces the 1944 bit LDPC codeword in accordance with selected first embodiments of the present disclosure.

FIG. 6 depicts a PPDU encoding parameter table specifying a second set of LDPC encoding parameters including a Navbits threshold for choosing between a 1944 bit LDPC codeword and a maximum LDPC codeword size of N×1944 bits in accordance with selected second embodiments of the present disclosure.

FIG. 7 depicts a PPDU encoding parameter table specifying a third set of LDPC encoding parameters including a Navbits threshold and specified conditions for choosing between a 1944 bit LDPC codeword and a maximum LDPC codeword size of N×1944 bits in accordance with selected third embodiments of the present disclosure.

FIG. 8 depicts a PPDU encoding parameter table specifying a fourth set of LDPC encoding parameters including a Navbits threshold and specified conditions for choosing between a 1944 bit LDPC codeword and a maximum LDPC codeword size of N×1944 bits in accordance with selected fourth embodiments of the present disclosure.

FIG. 9 depicts a PPDU encoding parameter table specifying a fifth set of LDPC encoding parameters including a Navbits threshold for a maximum LDPC codeword size of N×1944 bits in accordance with selected fifth embodiments of the present disclosure.

FIG. 10 depicts a PPDU encoding parameter table specifying a sixth set of LDPC encoding parameters including a maximum LDPC codeword size of N×1944 bits that is used for all cases where the number of codewords N_{CW}≥2 in accordance with selected sixth embodiments of the present disclosure.

FIG. 11 depicts a PPDU encoding parameter table specifying a seventh set of LDPC encoding parameters having a maximum LDPC codeword size of N×1944 bits which replaces the 1944 bit LDPC codeword in accordance with selected seventh embodiments of the present disclosure.

FIG. 12 depicts a PPDU encoding parameter table specifying a eighth set of LDPC encoding parameters having a maximum LDPC codeword size of N×1944 bits which replaces the 1944 bit LDPC codeword only when the number of codewords is even in accordance with selected seventh embodiments of the present disclosure.

FIG. 13 depicts a PPDU encoding parameter table specifying a ninth set of LDPC encoding parameters having a maximum LDPC codeword size of N×1944 bits which replaces the 1944 bit LDPC codeword only when the number of codewords is even and the number of available bits exceeds a Navbits threshold in accordance with selected ninth embodiments of the present disclosure.

FIG. 14 illustrates a flow diagram of a technique for wireless communications in accordance with selected embodiments of the present disclosure.

### DETAILED DESCRIPTION

A system, apparatus, and methodology are described for enabling wireless communication station (STA) devices to perform low-density parity-check (LDPC) encoding operations on one or more Physical Layer Protocol Data Units (PPDU) using LDPC codewords having codeword lengths greater than 1944 bits in compliance with emerging 802.11 standards, such as 802.11bn. As disclosed herein, LDPC encoding parameters that may be used for LDPC encoding and decoding are stored in one or more tables which use the number of available bits to specify a number of LDPC codewords and an associated LDPC codeword length, including one or more LDPC codewords having codeword lengths that equal an integer multiple of 1944 bits (e.g., N×1944), where the integer N≥2. In selected embodiments, an LDPC encoding parameter table is generated by modifying the 802.11n LDPC encoding parameter table to replace the 1944-bit codeword with a 1944×N bit codeword by including a new N_{avbits} threshold N1 for use with selecting between LDPC codeword lengths of 1296 bits and 1994×N bits. In other embodiments, an LDPC encoding parameter table is generated by modifying the 802.11n LDPC encoding parameter table to add a new 1944×N bit codeword and including a new N_{avbits} threshold N1 for use with selecting between LDPC codeword lengths of 1944 bits and 1994×N bits. In other embodiments, an LDPC encoding parameter table is generated by modifying the 802.11n LDPC encoding parameter table to replace each 1944 bit codeword with a new 1944×N bit codeword. In other embodiments, an LDPC encoding parameter table is generated by modifying the 802.11n LDPC encoding parameter table to add a new 1944×N bit codeword and to specify one or more selection conditions and/or N_{avbits} threshold values for choosing between LDPC codeword lengths of 1944 bits and 1994×N bits. In selected embodiments, a selection condition may be a defined threshold value N1, where the 1944×N bit codeword is chosen if the number of available bits N_{avbits}>N1. In other embodiments, a selection condition for selecting the 1944×N bit codeword may be a requirement that is based on the per-CW parity bits satisfying certain conditions, such as being smaller than a threshold for each code rate or being larger than a threshold for each code rate. In other embodiments, a selection condition for selecting the 1944×N bit codeword may be a requirement that the number of codewords is equal to or greater than 2. In other embodiments, a selection condition for selecting the 1944×N bit codeword may be a requirement that the number of codewords is even. In other embodiments, a selection condition for selecting the 1944×N bit codeword may be a requirement that the number of codewords is even and the number of available bits N_{avbits} exceeds a defined threshold value N1. In other selected embodiments, the transmitting/encoding STA chooses the LDPC encoding parameter table based on the receiver's capability and signals the chosen LDPC encoding parameter table to the receiving/decoding STA in the PPDU SIG field.

It will be readily understood that the components of the embodiments as generally described herein and illustrated in the appended figures could be arranged and designed in a wide variety of different configurations. Thus, the following more detailed description of various embodiments, as represented in the figures, is not intended to limit the scope of the present disclosure, but is merely representative of various embodiments. While the various aspects of the embodiments are presented in drawings, the drawings are not necessarily drawn to scale unless specifically indicated.

The present invention may be embodied in other specific forms without departing from its spirit or essential characteristics. The described embodiments are to be considered in all respects only as illustrative and not restrictive. The scope of the invention is, therefore, indicated by the appended claims rather than by this detailed description. All changes which come within the meaning and range of equivalency of the claims are to be embraced within their scope.

Reference throughout this specification to features, advantages, or similar language does not imply that all of the features and advantages that may be realized with the present invention should be or are in any single embodiment of the invention. Rather, language referring to the features and advantages is understood to mean that a specific feature, advantage, or characteristic described in connection with an embodiment is included in at least one embodiment of the present invention. Thus, discussions of the features and advantages, and similar language, throughout this specification may, but do not necessarily, refer to the same embodiment.

Furthermore, the described features, advantages, and characteristics of the invention may be combined in any suitable manner in one or more embodiments. One skilled in the relevant art will recognize, in light of the description herein, that the invention can be practiced without one or more of the specific features or advantages of a particular embodiment. In other instances, additional features and advantages may be recognized in certain embodiments that may not be present in all embodiments of the invention.

Reference throughout this specification to “one embodiment”, “an embodiment”, or similar language means that a particular feature, structure, or characteristic described in connection with the indicated embodiment is included in at least one embodiment of the present invention. Thus, the phrases “in one embodiment,” “in an embodiment,” and similar language throughout this specification may, but do not necessarily, all refer to the same embodiment.

In embodiments of a wireless communications system, an access point (AP) affiliated with an AP multi-link device (MLD) (e.g., wireless device) of a wireless local area network (WLAN) transmits data to at least one associated non-AP station (STA) affiliated with a non-AP STA MLD (e.g., a STA MLD). The AP MLD is configured to operate with associated non-AP MLDs according to a communication protocol. For example, the communication protocol may be an Ultra-High Reliability (UHR) communication protocol, or Institute of Electrical and Electronics Engineers (IEEE) 802.11be communication protocol, or future versions of such protocols that are being developed. Features of wireless communications and multi-link communication systems operating in accordance with the UHR communication protocol and/or next-generation communication protocols may be referred to herein as “non-legacy” features. In some embodiments of the wireless communications system described herein, different associated STAs within range of an AP operating according to the UHR communication protocol are configured to operate according to at least one other communication protocol, which defines operation in a Basic Service Set (BSS) with the AP, but are generally affiliated with lower data throughput protocols. The lower data throughput communication protocols (e.g., IEEE 802.11n, IEEE 802.11ac, IEEE 802.11ax, etc.) may be collectively referred to herein as “legacy” communication protocols.

As indicated above, 802.11 standards have introduced various signaling modulation and communication techniques to enable higher data transmission rates. For example, the IEEE 802.11n standard introduce LDPC codes with three different code word lengths: 648, 1296, 1944. LDPC coding is used for error correction when data is transmitted over PPDUs. PPDUs contain, in addition to the data, a preamble with multiple fields that provide demodulation information, as well as other information for reception. At the time when the IEEE 802.11n standard was introduced, the maximum supported bandwidth was 40 MHz and there were limited modulation schemes. However, with the introduction of larger operation bandwidths (up to 320 MHz) and higher modulations, the 802.11n codeword lengths have not kept pace with the newer signaling modulation and communication techniques. To address this limitation and improve wireless data transmission performance and system throughput, longer codeword lengths have been proposed, but updated LDPC PPDU encoding parameters are needed which correspond to the added LDPC codeword lengths, which is needed in the more recent IEEE standards, 802.11bn.

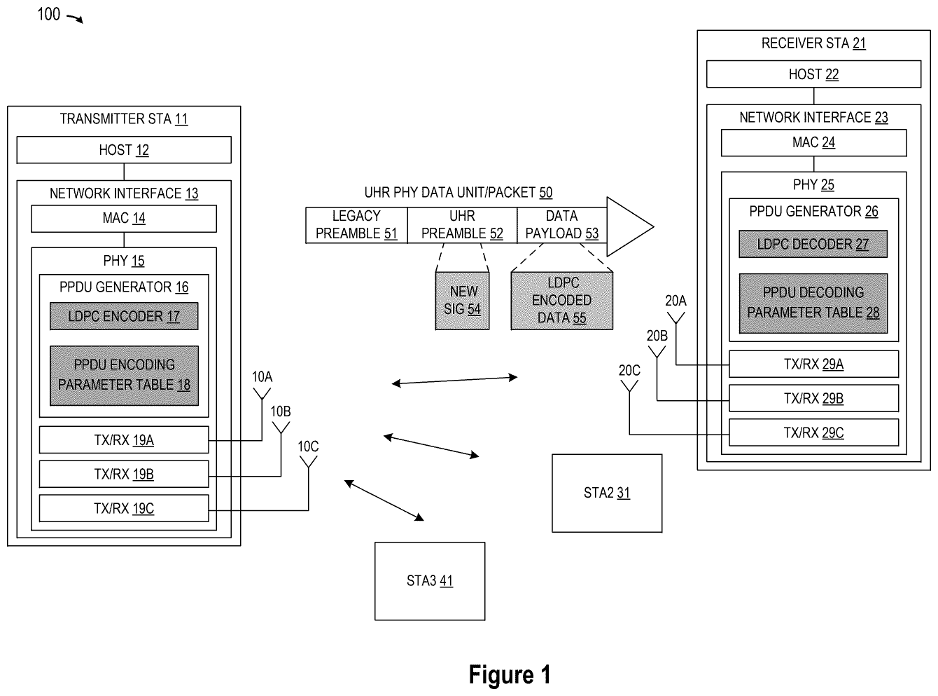

To provide an improved understanding of selected embodiments of the present disclosure, reference is now made to FIG. 1 which depicts a block diagram of a wireless communications system 100, such as a wireless local area network (WLAN), in which a transmitter access point (AP) station (STA) 11 and one or more wireless devices 21, 31, 41 use MIMO transmit beamforming to transmit and receive data packets. As depicted, the transmitter STA 11 includes a host processor 12 coupled to a network interface 13. In selected embodiments, the network interface 13 includes one or more integrated circuits (IC) devices configured to operate a local area network (LAN) protocol. To this end, the network interface 13 may include a medium access control (MAC) processor 14 and a physical layer (PHY) processor 15. In selected embodiments, the MAC processor 14 is implemented as an 802.11bn MAC processor 14, and the PHY processor 15 is implemented as an 802.11bn PHY processor 15. The PHY processor 15 includes a plurality of transceivers 19A-C which are coupled to a plurality of antennas 10A-C. Although three transceivers 19A-C and three antennas 10A-C are illustrated, the transmitter STA 11 may use any suitable number of transceivers 19 and antennas 10 in other embodiments. In addition, the transmitter STA 11 may have more antennas 10 than transceivers 19, in which case antenna switching techniques are used to switch the antennas 10 between the transceivers 19. In selected embodiments, the MAC processor 14 is implemented with one or more integrated circuit (IC) devices, and the PHY processor 15 is implemented on one or more additional IC devices. In other embodiments, at least a portion of the MAC processor 14 and at least a portion of the PHY processor 15 are implemented on a single IC device. In various embodiments, the MAC processor 14 and the PHY processor 15 are configured to operate according to at least a first communication protocol (e.g., 802.11bn). In other embodiments, the MAC processor 14 and the PHY processor 15 are also configured to operate according to one or more additional communication protocols (e.g., according to the IEEE 802.11ax Standard). Using the communication protocol(s), the transmitter STA 11 is operative to create a wireless local area network (WLAN) 100 in which one or more client stations (e.g., 21) may communicate with the transmitter STA 11 and/or with other client stations (e.g., 31, 41) located within the WLAN 100. Although three client stations 21, 31, 41, are illustrated in FIG. 1, the WLAN 100 may include any suitable number of client stations in various scenarios and embodiments.

At least one of the client stations (e.g., client station 21) is configured to operate as a receiver STA in accordance with the first communication protocol. To this end, the receiver STA 21 includes a host processor 22 coupled to a network interface 23. In selected embodiments, the network interface 23 includes one or more IC devices configured to operate as discussed below. For example, the depicted network interface 23 may include a MAC processor 24 and a PHY processor 25. In selected embodiments, the MAC processor 24 is implemented as an 802.11bn MAC processor 24, and the PHY processor 25 is implemented as an 802.11bn PHY processor 25. The PHY processor 25 includes a plurality of transceivers 29A-C coupled to a plurality of antennas 20A-C. Although three transceivers 29A-C and three antennas 20A-C are illustrated, the receiver STA 21 may include any suitable number of transceivers 29 and antennas 20. In addition, the receiver STA 21 may include more antennas 20 than transceivers 29, in which case antenna switching techniques are used. In selected embodiments, the MAC processor 24 is implemented on at least a first IC device, and the PHY processor 25 is implemented on at least a second IC device. In other embodiment, at least a portion of the MAC processor 24 and at least a portion of the PHY processor 25 are implemented on a single IC device. As will be appreciated, one or more of the client stations 31, 41 may have a structure that is the same as or similar to the receiver STA 21, though there can be structural differences.

As disclosed herein, the AP STA 11 transmits data streams to one or more client stations 21, 31, 41 in the WLAN 100. The AP STA 11 is configured to operate with client stations (e.g., 21) according to at least a first communication protocol which may be referred to as “ultra-high reliability” or UHR communication protocol or IEEE 802.11bn communication protocol. In some embodiments, different client stations in the vicinity of the AP STA 11 are configured to operate according to one or more other communication protocols which define operation in some of the same frequency band(s) as the UHR communication protocol but with generally lower data throughputs. Such lower data throughput communication protocols (e.g., IEEE 802.11a, IEEE 802.11n, IEEE 802.11ac, 802.11ax and/or 802.11be) are collectively referred herein as “legacy” communication protocols.

In the context of the present disclosure, it will be understood by those skilled in the art that the IEEE 802.11 standard (a.k.a., Wi-Fi) has been amended to provide very high data throughput performance in real-world, high density scenarios. For example, there are advanced Physical Layer techniques being addressed in IEEE 802.11bn standard which add more flexibility to the orthogonal frequency-division multiple access (OFDMA) modulation schemes by increasing (i) the number of modulation and coding schemes (MCS), (ii) the unequal modulation across spatial streams. Unfortunately, existing 802.11 wireless encoding schemes do not support longer LDPC codewords for efficient encoding of the new MCS schemes and/or higher order modulation schemes. As a result, the data encoding and signaling schemes from 802.11n must be modified to support larger length LDPC codewords, while at the same time continuing to satisfy all the current use cases requirements and ensure backwards compatibility to existing IEEE 802.11 standards.

To address these and other shortcomings of the existing 802.11 capabilities, an improved LDPC encoder/decoder is provided at each STA device which is configured to encode PPDU data using one or more LDPC codewords that are longer than 1944 bits. In addition, an 802.11-compliant information field is provided to signal the number and length of different LDPC codewords, including one or more LDPC codewords that are longer than 1944 bits. To this end, each transmitting STA device (e.g., AP STA 11) includes an LDPC encoder (e.g., 17) which is configured to encode PPDU data using one or more LDPC codeword encoding data that is stored in a PPDU encoding parameter table 18 for transmission. In selected embodiments of the present disclosure, the AP STA device 11 uses the LDPC encoder 17 to generate a defined SIG User Info field 54 in the UHR PHY data unit/packet 50 which specifies the number and length of LDPC codewords used by the AP STA device 11 to encode the PPDU data so that receiver STA device 21 can correctly decode the subsequently-received data packet. In similar fashion, the non-AP STA device 21 uses the LDPC decoder 27 and PPDU decoding parameter table 28 to correctly process and decode the subsequently received data packet.

In selected embodiments for signaling LDPC encoding information to a receiver 21, the transmitter 11 may include a PPDU generator module 16 which is configured to generate a UHR PHY data unit or packet frame 50 which has a legacy preamble portion 51, a UHR preamble portion 52, and an (optional) data payload portion 53. The contents of the legacy and UTH preamble portions 51, 52 are known to those skilled in the art, and will not be detailed other than to note that the UHR preamble portion 52 may include a defined SIG User Info field 54 having common information field (with information for all users) and a user-specified field (with information about the number and length of LDPC codewords, MCS, the number of spatial streams (Nss), unequal modulation pattern, etc.). And for upstream transmissions to the transmitter 11, the receiver 21 may signal LDPC encoding information to the transmitter 11 with the PPDU generator module 26 which is configured to generate a UHR PHY data unit or packet frame (not shown) which has a legacy preamble portion, a UHR preamble portion, and an (optional) data payload portion, where the UHR preamble portion includes, inter alia, a defined SIG User Info field conveying information about the number and length of LDPC codewords used to encode PPDU data transmitted from the non-AP 21 to the transmitter 11.

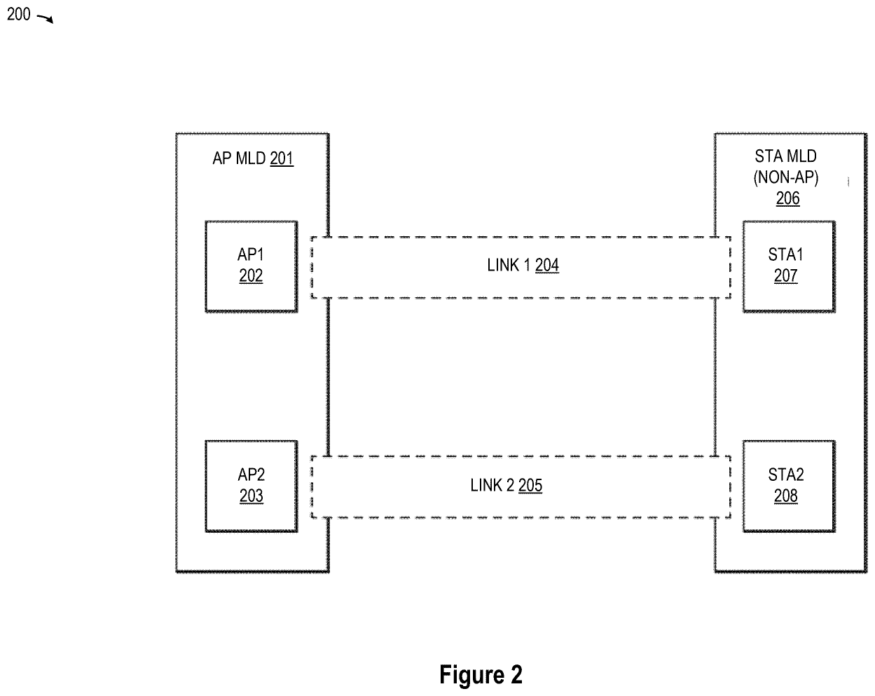

To provide additional details for an improved understanding of selected embodiments of the present disclosure, reference is now made to FIG. 2 which depicts a simplified block diagram of a multi-link communications system 200 that is used for wireless (e.g., WiFi) communications. As depicted, the multi-link communications system 200 includes one AP multi-link device (MLD) 201 and one non-AP STA MLD 206. The multi-link communications system 200 can be used in various applications, such as industrial applications, medical applications, computer applications, and/or consumer or enterprise applications. In some embodiments, the multi-link communications system 200 may be a wireless communications system, such as a wireless communications system compatible with an IEEE 802.11 protocol. For example, the multi-link communications system may be a wireless communications system compatible with an IEEE 802.11bn protocol. Although the depicted multi-link communications system 200 is shown with certain components and described with certain functionality herein, other embodiments of the multi-link communications system 200 may include fewer or more components to implement the same, less, or more functionality. For example, in some embodiments, the multi-link communications system 200 includes a single AP MLD with multiple STA MLDs, or multiple AP MLDs with more than one STA MLD. In some embodiments, the legacy STAs (non-HE STAs) may associate with one of the APs affiliated with the AP MLD. And while the multi-link communications system 200 is shown as being connected in a certain topology, the network topology of the multi-link communications system 200 is not limited to the depicted.

The depicted AP MLD 201 includes two radios, AP1 202 and AP2 203. In selected embodiments, a common part of the AP MLD 201 implements upper layer Media Access Control (MAC) functionalities (e.g., beaconing, association establishment, reordering of frames, etc.) and a link-specific part of the AP MLD 201 (i.e., the APs 202, 203) implement lower layer MAC functionalities (e.g., backoff, frame transmission, frame reception, etc.). The APs 202, 203 may be implemented in hardware (e.g., circuits), software, firmware, or a combination thereof. The APs 202, 203 may be fully or partially implemented as an integrated circuit (IC) device. In some embodiments, the APs 202, 203 may be wireless APs compatible with at least one WLAN communications protocol (e.g., at least one IEEE 802.11 protocol). For example, the APs 202, 203 may be wireless APs compatible with an IEEE 802.11bn protocol. In some embodiments, an AP MLD 201 connects to a local network (e.g., a LAN) and/or to a backbone network (e.g., the Internet) through a wired connection and wirelessly connects to wireless STAs, for example, through one or more WLAN communications protocols, such as an IEEE 802.11 protocol. In some embodiments, an AP (e.g., AP1 202 and/or AP2 203) includes at least one antenna, at least one transceiver operably connected to the at least one antenna, and at least one controller operably connected to the corresponding transceiver. In some embodiments, at least one transceiver includes a physical layer (PHY) device. The at least one controller may be configured to control the at least one transceiver to process received packets through the at least one antenna. In some embodiments, the at least one controller may be implemented within a processor, such as a microcontroller, a host processor, a host, a digital signal processor (DSP), or a central processing unit (CPU), which can be integrated in a corresponding transceiver. In some embodiments, each of the APs 202, 203 may operate in a different BSS operating channel. For example, AP1 202 may operate in a 320 MHz (one million hertz) BSS operating channel at 6 Gigahertz (GHz) band and AP2 203 may operate in a 160 MHz BSS operating channel at 5 GHz band. Although the AP MLD 201 is shown as including two APs, other embodiments of the AP MLD 201 may include more than two APs.

In similar fashion, the depicted non-AP STA multi-link device 206 includes two radios which are implemented as non-AP STAs, STA1 207 and STA2 208. The STAs 207, 208 may be implemented in hardware (e.g., circuits), software, firmware, or a combination thereof. The STAs 207, 208 may be fully or partially implemented as an IC device. In some embodiments, the non-AP STAs 207, 208 are part of the STA MLD 207, such that the STA MLD may be a communications device that wirelessly connects to a wireless AP MLD. For example, the STA MLD 206 may be implemented in a laptop, a desktop personal computer (PC), a mobile phone, or other communications device that supports at least one WLAN communications protocol. In some embodiments, the non-AP STA MLD 206 is a communications device compatible with at least one IEEE 802.11 protocol (e.g., an IEEE 802.11bn protocol). In some embodiments, the STA MLD 206 implements a common MAC data service interface and the non-AP STAs 207, 208 implement a lower layer MAC data service interface.

In some embodiments, the AP MLD 201 and/or the STA MLD 206 may identify which communication links support multi-link operation during a multi-link operation setup phase and/or exchanges information regarding multi-link capabilities during the multi-link operation setup phase. In some embodiments, each of the non-AP STAs 207, 208 of the STA MLD 206 may operate in a different frequency band. For example, the non-AP STA 207 may operate in the 2.4 GHz frequency band and the non-AP STA 208 may operate in the 5 GHz frequency band. In some embodiments, each STA includes at least one antenna, at least one transceiver operably connected to the at least one antenna, and at least one controller connected to the corresponding transceiver. In some embodiments, at least one transceiver includes a PHY device. The at least one controller may be configured to control the at least one transceiver to process received packets through the at least one antenna. In some embodiments, the at least one controller may be implemented within a processor, such as a microcontroller, a host processor, a host, a DSP, or a CPU, which can be integrated in a corresponding transceiver.

In operation, the STA MLD 206 communicates with the AP MLD 201 via two communication links, link 1 204 and link 2 205. For example, each of the non-AP STAs 207, 208 communicates with an AP 202, 203 via corresponding communication links 204, 205. In an embodiment, a communication link (e.g., link 1 204 or link 2 205) may include a BSS operating channel established by an AP (e.g., AP1 202 or AP2 203) that features multiple 20 MHz channels used to transmit frames (e.g., Physical Layer Convergence Protocol (PLCP) Protocol Data Units (PPDUs), Beacon frames, management frames, etc.) between a first wireless device (e.g., an AP, an AP MLD, an STA, or an STA MLD) and a second wireless device (e.g., an AP, an AP MLD, an STA, or an STA MLD). In some embodiments, a 20 MHz channel may be a punctured 20 MHz channel or an unpunctured 20 MHz channel. Although the STA MLD 206 is shown as including two non-AP STAs 207, 208, other embodiments of the STA MLD 206 may include one non-AP STA or more than two non-AP STAs. In addition, although the AP MLD 201 communicates (e.g., wirelessly communicates) with the STA MLD 206 via the communications links 204, 205, in other embodiments, the AP MLD 201 may communicate (e.g., wirelessly communicate) with the STA MLD 206 via more than two communication links or less than two communication links.

In some embodiments, a first MLD (e.g., an AP MLD 201 or non-AP MLD (STA MLD) 206) may transmit management frames in a multi-link operation with a second MLD (e.g., STA MLD 206 or AP MLD 201) to coordinate the multi-link operation between the first MLD and the second MLD. As an example, a management frame may be a channel switch announcement frame, a (Re) Association Request frame, a (Re) Association Response frame, a Beacon frame, a Disassociation frame, an Authentication frame, and/or a Block Acknowledgement (Ack) (BA) Action frame, etc. In some embodiments, one or more management frames may be transmitted via a cross-link transmission (e.g., according to an IEEE 802.11bn communication protocol). As an example, a cross-link management frame transmission may involve a management frame being transmitted and/or received on one link (e.g., link 1 204) while carrying information of another link (e.g., link 2 205). In some embodiments, a management frame is transmitted on any link (e.g., at least one of two links or at least one of multiple links) between a first MLD (e.g., AP MLD 201) and a second MLD (e.g., STA MLD 206). As an example, a management frame may be transmitted between a first MLD and a second MLD on any link (e.g., at least one of two links or at least one of multiple links) associated with the first MLD and the second MLD.

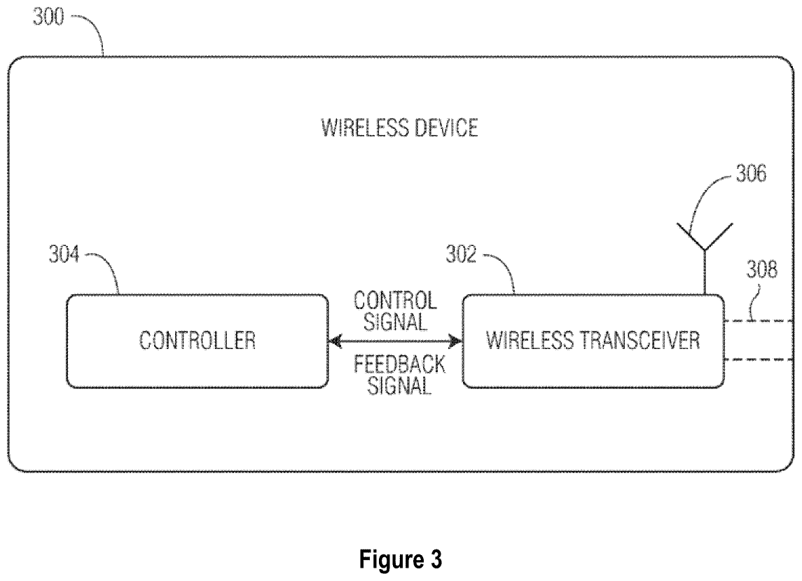

To provide additional details for an improved understanding of selected embodiments of the present disclosure, reference is now made to FIG. 3 which depicts a wireless device 300 which can be used in the wireless communications system 100 depicted in FIG. 1 and/or the multi-link communications system 200 depicted in FIG. 2. For example, the wireless device 300 may be an embodiment of the transmitter STA 11 and/or the receiver STA 21 depicted in FIG. 1. As depicted, the wireless device 300 includes a wireless transceiver 302, a controller 304 operably connected to the wireless transceiver, and at least one antenna 306 operably connected to the wireless transceiver 302. In some embodiments, the wireless device 300 may include at least one optional network port 308 operably connected to the wireless transceiver 302. In some embodiments, the wireless transceiver 302 includes a physical layer (PHY) device. The wireless transceiver 302 may be any suitable type of wireless transceiver. For example, the wireless transceiver 302 may be a LAN transceiver (e.g., a transceiver compatible with an IEEE 802.11 protocol). In some embodiments, the wireless device 300 includes multiple transceivers. The controller 304 may be configured to control the wireless transceiver 302, such as by generating a control signal, to process packets received through the antenna 306 and/or the network port 308 and/or to generate outgoing packets to be transmitted through the antenna 306 and/or the network port 308. In some embodiments, the wireless transceiver 302 transmits one or more feedback signals to the controller 304. In some embodiments, the controller 304 is implemented within a processor, such as a microcontroller, a host processor, a host, a DSP, or a CPU. In some embodiments, the wireless transceiver 302 is implemented in hardware (e.g., circuits), software, firmware, or a combination thereof. The antenna 306 may be any suitable type of antenna. For example, the antenna may be an induction type antenna such as a loop antenna or any other suitable type of induction type antenna. However, the antenna is not limited to an induction type antenna. The network port 308 may be any suitable type of port.

In accordance with selected embodiments of the present disclosure, the controller 304 is configured to generate a control signal and the wireless transceiver 302 is configured to, in response the control signal, perform a low-density parity-check (LDPC) encoding operation to generate an encoded data unit. In some embodiments, the encoded data includes a physical layer protocol data unit (PPDU). In some embodiments, the wireless transceiver 302 responds to the control signal to perform LDPC encoding operations using LDPC codewords having codeword lengths greater than 1944 bits in compliance with emerging 802.11 standards, such as 802.11bn. As disclosed herein, the wireless transceiver 302 accesses one or more LDPC encoding parameter tables to select the number and length of LDPC codewords based on the number of available bits, where the LDPC encoding parameter tables include one or more LDPC codewords having codeword lengths that equal an integer multiple of 1944 bits (e.g., N×1944), where the integer N≥2. For example, an LDPC encoding parameter table includes a 1944×N bit codeword along with a N_{avbits} threshold and/or one or more selection conditions for use with selecting the 1944×N bit codeword. In some embodiments, the wireless device 300 is compatible with an Institute of Electrical and Electronics Engineers (IEEE) 802.11 protocol. In some embodiments, the wireless device is a component of a multi-link device (MLD).

As will be appreciated by those skilled in the art, the IEEE 802.11n standard describes LDPC encoding operations for encoding an LDPC PPDU with reference to steps (a) through step (g).

In step (a), the number of available bits, Navbits, is computed for the minimum number of OFDM symbols in which the Data field of the packet may fit. In particular, the number of available bits is computed as:

$$Navbits = {N}_{CBPS} \times ⌈ \frac{{N}_{pld}}{{N}_{CBPS} * R} ⌉$$

where N_{pld}=length×8+16, where length is the value of the High Throughput (HT) Length field in the HT-SIG (signal field), and where N_{pld} is the number of bits in the Physical Layer Convergence Protocol (PLCP) service data unit (PSDU) and SERVICE field, and where R is the coding rate.

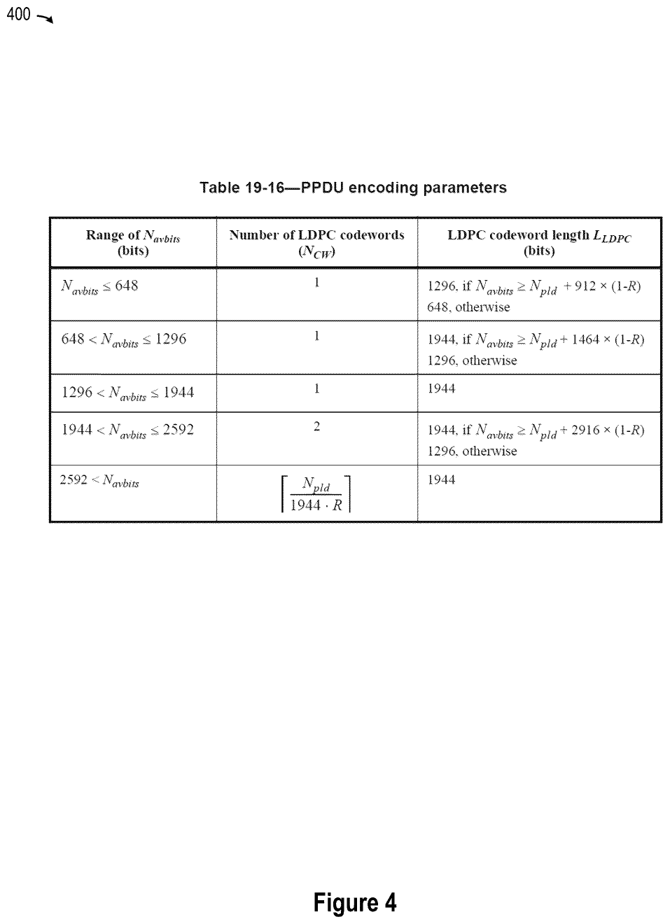

In step (b), the integer number of LDPC codewords (N_{CW}) and the length of the LDPC codewords to be used (L_{LDPC}) to be transmitted is computed. In selected embodiments, the number and length of LDPC codewords (N_{CW}, L_{LDPC}) may be computed by using the computed number of available bits, Navbits, to perform a table lookup operation in a PPDU encoding parameters table. For example, FIG. 4 depicts a physical layer protocol data unit (PPDU) encoding parameter table 400 specifying a conventional set of LDPC encoding parameters having a maximum LDPC codeword size of 1944 bits in accordance with the IEEE 802.11n standard. The computational requirements for defining the number of LDPC codeworks (N_{CW}) and the LDPC codeword length (L_LDPC) values need to be belabored here since they are known to those skilled in the art, other than to note that the computed number of available bits (Navbits) is used to choose an entry in the “Range of Navbits” column from which the corresponding row values for the number of LDPC codeworks (N_{CW}) and the LDPC codeword length (L_LDPC) values are chosen. For example, if the computed number of available bits Navbits≤648 bits, then the N_{CW} value is 1, and the 1296-bit codeword is selected if Navbits≥N_{pld}+912×(1−R)—otherwise, the 648-bit codeword is selected. And if the computed number of available bits is 648<Navbits≤1296 bits, then the N_{CW} value is 1, and the 1944-bit codeword is selected if Navbits≥N_{pld}+1464×(1−R)—otherwise, the 1296-bit codeword is selected. And if the computed number of available bits is 1296<Navbits≤1944 bits, then the N_{CW} value is 1, and the 1944-bit codeword is selected. And if the computed number of available bits is 1944<Navbits≤2592 bits, then the N_{CW} value is 2, and the 1944-bit codeword is selected if Navbits≥N_{pld}+2916×(1−R)—otherwise, the 1296-bit codeword is selected. And if the computed number of available bits Navbits>2592, then the N_{CW} value is N_{pld}/(1944×R), and the 1944-bit codeword is selected.

The 802.11n standard also described steps for computing the number of shortening bits, Nₛₕᵣₜ, to be added to the N_{pld} data bits before encoding at step (c). In addition, the 802.11n standard described steps for computing the number of bits to be punctured, N_{punc}, to be punctured from codewords after encoding at step (d). The 802.11n standard also described steps for computing the number of coded bits to be repeated, Nᵣₑₚ, after discarding the punctured bits at step (e). For each of the N_{CW} codewords, the 802.11n standard described step (f) for processing the data using the number of shorting bits per codeword (Nₛₕᵣₜ) for encoding, the number of bits to be punctured, N_{punc}, and the number of coded bits to be repeated, Nᵣₑₚ per codeword. Finally, the 802.11n standard described step (g) for aggregating and parsing all codewords. Since the specific processing details of the computational steps (a)-(g) are known to those skilled in the art, they will not be detailed here other than to note that the 802.11n PPDU encoding parameter table 400 specifies only three different LDPC codeword lengths: 648, 1296, and 1944 bits. To enable the addition of longer LDPC codeword lengths (e.g., N×1944, where N is an integer larger than 1), the PPD encoding parameters table must be modified or updated to allow the selection of longer LDPC codeword lengths.

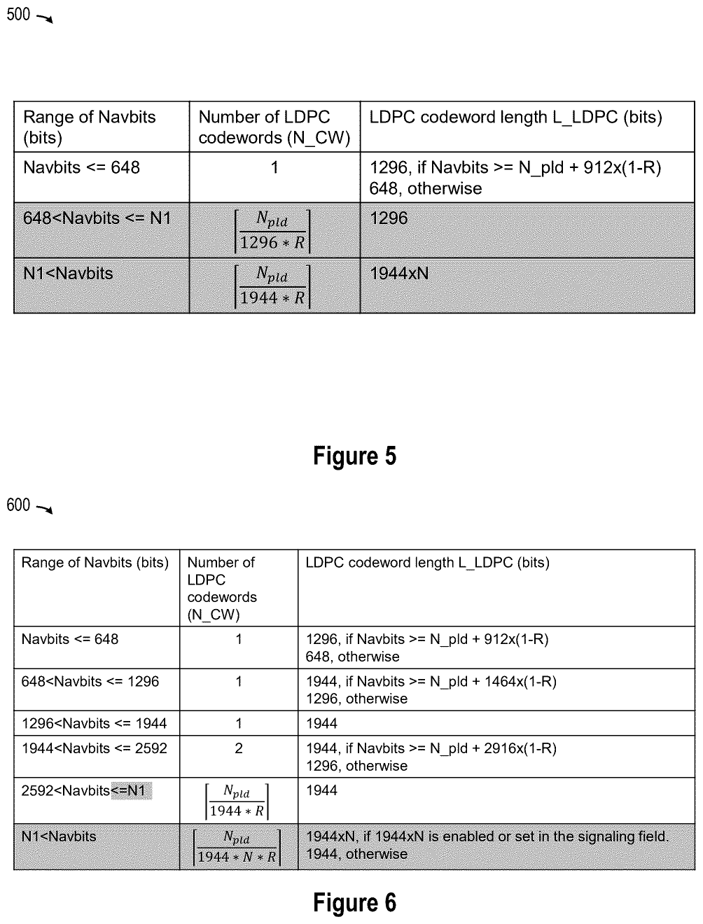

Referring now to FIG. 5, there is depicted a PPDU encoding parameter table 500 in accordance with selected first embodiments of the present disclosure. As depicted, the PPDU encoding parameter table 500 specifies a first set of LDPC encoding parameters including a Navbits threshold N1 for selecting a maximum LDPC codeword size of N×1944 bits when number of available bits Navbits>N1. In this example, the PPDU encoding parameter table 500 is generated by modifying the 802.11n PPDU encoding parameter table 400 to remove the LDPC codeword length (L_LDPC) entries for Navbits>648 bits, and to add new table entries (indicated in gray), including a new 1296-bit codeword and longer 1944×N-bit codeword with a Navbits threshold N1 for choose between the 1296-bit codeword and the new longer 1944×N-bit codeword. As a result, if the number of the available bits Navbits is 648<Navbits≤N1, then the 1296-bit codeword is selected. However, if the number of the available bits Navbits exceeds N1 (e.g., Navbits>N1), then the 1944×N-bit codeword is selected. For the new 1296-bit codeword, the number of LDPC codewords N_{CW}=N_{pld}/(1296×R), and for the longer 1944×N-bit codeword, the number of LDPC codewords N_{CW}=N_{pld}/(1944×R). As disclosed herein, the PPDU encoding parameter table 500 and the 802.11n PPDU encoding parameter table may both be stored at the transmitting STA, and the selection of which table to use may be determined on the basis of the receiver's LDPC capability. In addition or in the alternative, the selection of the PPDU encoding parameter table 500 with longer LDCP codeword lengths may be signaled in the SIG field sent by the transmitter. As will be appreciated, the PPDU encoding parameter table 500 may include more than one new LDPC codeword length, in which case there should be defined one threshold for each codeword length.

Referring now to FIG. 6, there is depicted a PPDU encoding parameter table 600 in accordance with selected second embodiments of the present disclosure. As depicted, the PPDU encoding parameter table 600 specifies a second set of LDPC encoding parameters including a Navbits threshold N1 for choosing between a 1944-bit LDPC codeword and a maximum LDPC codeword size of N×1944 bits. In this example, the PPDU encoding parameter table 600 is generated by modifying the 802.11n PPDU encoding parameter table 400 to keep the LDPC codeword length (L_LDPC) entries up to the 1944-bit codeword, but to add a longer 1944×N-bit codeword with a Navbits threshold N1 for the 1944-bit codeword (as indicated in gray) for choosing between the 1944-bit codeword and the new longer 1944×N-bit codeword. As a result, if the number of the available bits Navbits is 2592<Navbits≤N1, then the 1944-bit codeword is selected. In one example, N1 is equal to the codeword length 1944×N. However, if the number of the available bits Navbits exceeds N1 (e.g., Navbits>N1), then the 1944×N-bit codeword is selected if 1944×N is enabled by the transmitter and set in the signaling field—otherwise, the 1944-bit codeword is selected. For the 1944-bit codeword, the number of LDPC codewords N_{CW}=N_{pld}/(1944×R), and for the longer 1944×N-bit codeword, the number of LDPC codewords N_{CW}=N_{pld}/(1944×N×R). As disclosed herein, the selection of the PPDU encoding parameter table 600 with longer LDCP codeword lengths may be further decided by the transmitter and signaled in the SIG field sent by the transmitter. As will be appreciated, the PPDU encoding parameter table 600 may include more than one new LDPC codeword length, in which case there should be defined one threshold for each codeword length. In one example where N=2, then N1=3888, and if the number of the available bits Navbits is 2592<Navbits≤N1=3888, the number of codeword

$$⌈ \frac{{N}_{pld}}{1944 * R} ⌉ = 2 .$$

The encoding table in FIG. 6 is simplified as below.

| | Number of LDPC | |
|---|---|---|
| Range of Navbits (bits) | codewords (N_CW) | LDPC codeword length L_LDPC (bits) |
| Navbits <= 648 | 1 | 1296, if Navbits >= N_pld + 912x(1-R) |
| | | 648, otherwise |
| 648 < Navbits <= 1296 | 1 | 1944, if Navbits >= N_pld + 1464x(1-R) |
| | | 1296, otherwise |
| 1296 < Navbits <= 1944 | 1 | 1944 |
| 1944 < Navbits <= 2592 | 2 | 1944, if Navbits >= N_pld + 2916x(1-R) |
| | | 1296, otherwise |
| 2592 < Navbits <= 3888 | 2 | 1944 |
| 3888 < Navbits | $⌈ \frac{{N}_{pld}}{1944 * 2 * R} ⌉$ | 1944x2, if 1944x2 is enabled/set in the signaling field, |
| | | 1944 otherwise |

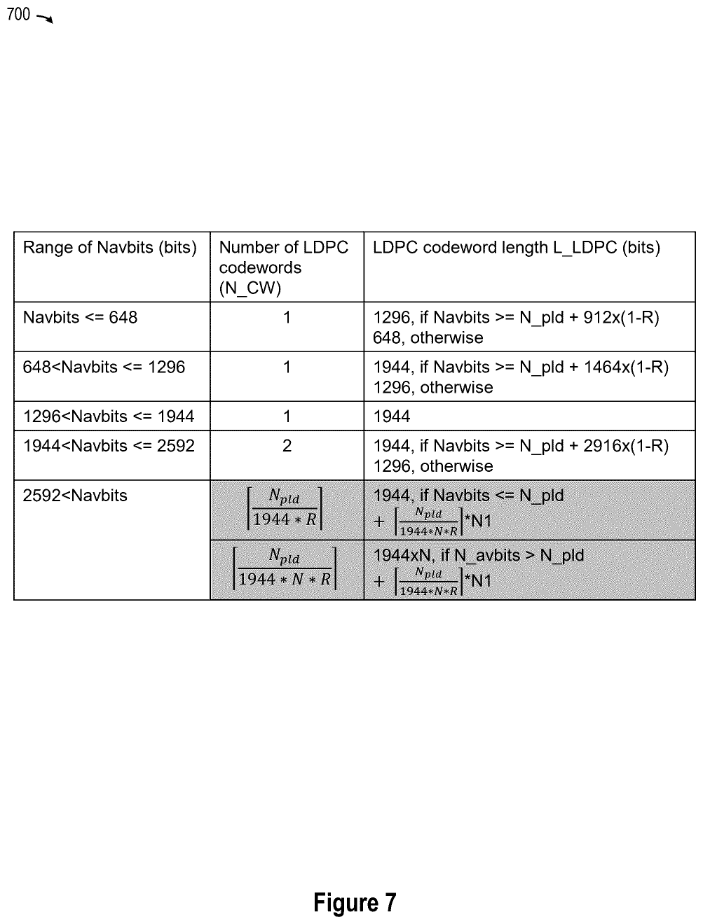

Referring now to FIG. 7, there is depicted a second example of a PPDU encoding parameter table 600 in accordance with selected third embodiments of the present disclosure. As depicted, the PPDU encoding parameter table 700 specifies a third set of LDPC encoding parameters including a Navbits threshold N1 and specified conditions for choosing between a 1944 bit LDPC codeword and a maximum LDPC codeword size of N×1944 bits. In the first example, the PPDU encoding parameter table 700 is generated by modifying the 802.11n PPDU encoding parameter table 400 to keep the LDPC codeword length (L_LDPC) entries up to the 2592 bit range of Navbits, but to conditionally add a longer 1944×N-bit codeword above the 2592 bit range of Navbits by specifying a Navbits threshold

$$N 2 = ( {N}_{pld} + ⌈ \frac{{N}_{pld}}{1944 * N * R} ⌉ \times N 1 )$$

(as indicated in gray) for choosing between the 1944-bit codeword and the new longer 1944×N-bit codeword. As a result, if the number of the available bits 2592<Navbits≤N2, then the 1944-bit codeword is selected. However, if the number of the available bits Navbits exceeds N2 (e.g., Navbits>N2), then the 1944×N-bit codeword is selected. For the 1944-bit codeword, the number of LDPC codewords N_{CW}=N_{pld}/(1944×R), and for the longer 1944×N-bit codeword, the number of LDPC codewords N_{CW}=N_{pld}/(1944×N×R). As seen from the foregoing, the specified condition for choosing between the 1944-bit codeword and the new longer codeword 1944×N-bit codeword is dependent on the per-CW parity bits. In this first example, for any Navbits>2592, the PPDU encoding parameter table 700 chooses the new longer codeword 1944×N if

$$( Navbits - {N}_{pld} ) / ⌈ \frac{{N}_{pld}}{1944 * N * R} ⌉ > N 1 , i . e . , Navbits > {N}_{pld} + ⌈ \frac{{N}_{pld}}{1944 * N * R} ⌉ * N 1.$$

In this case, the N_{avbits} threshold value N1 is lookup table dependent on the code rate N1(R). Alternatively, the Navbits threshold value N1 is defined as a fixed ratio N1=1944*N*(1−R)*N2, where N2 is a fixed ratio. As will be appreciated, the PPDU encoding parameter table 700 may include more than one new LDPC codeword length, in which case there should be defined one threshold for each codeword length.

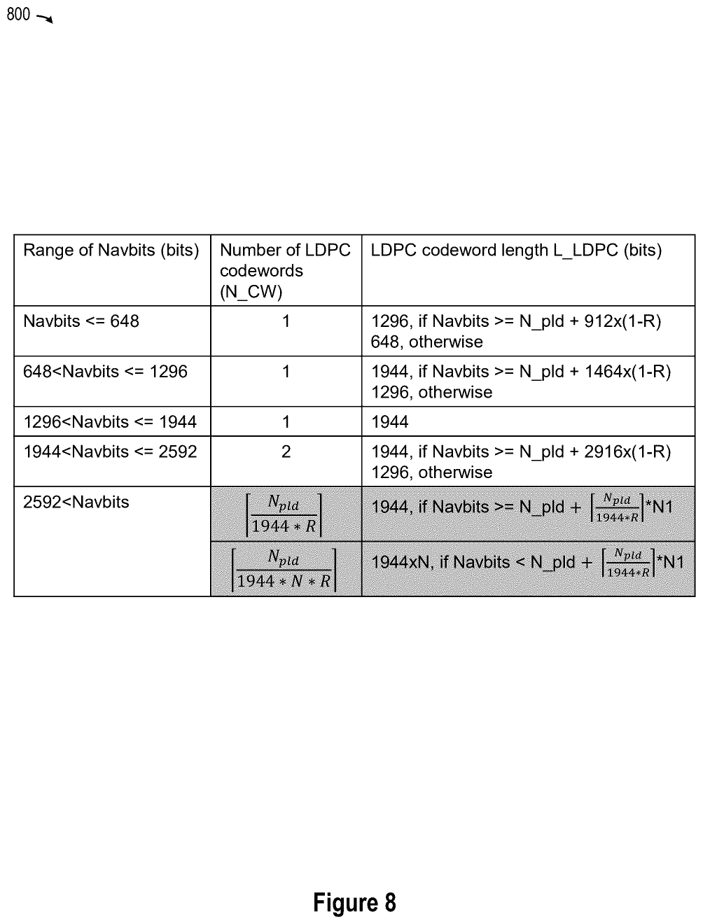

Referring now to FIG. 8, there is depicted a second example of a PPDU encoding parameter table 800 in accordance with selected fourth embodiments of the present disclosure. As depicted, the PPDU encoding parameter table 800 specifies a fourth set of LDPC encoding parameters including a Navbits threshold N1 and specified conditions for choosing between a 1944 bit LDPC codeword and a maximum LDPC codeword size of N×1944 bits. In the second example, the PPDU encoding parameter table 800 is generated by modifying the 802.11n PPDU encoding parameter table 400 to keep the LDPC codeword length (L_LDPC) entries up to the 2592 bit range of Navbits, but to conditionally add a longer 1944×N-bit codeword above the 2592 bit range of Navbits by specifying a Navbits threshold N3=(N_{pld}+[N_{pld}/(1944×R)]×N1) (as indicated in gray) for choosing between the 1944-bit codeword and the new longer 1944×N-bit codeword. As a result, if the number of the available bits 2592<Navbits<N3, then the 1944×N-bit codeword is selected. However, if the number of the available bits Navbits equals or exceeds N3 (e.g., Navbits≥N3), then the 1944-bit codeword is selected. For the 1944-bit codeword, the number of LDPC codewords N_{CW}=N_{pld}/(1944×R), and for the longer 1944×N-bit codeword, the number of LDPC codewords N_{CW}=N_{pld}/(1944×N×R). As seen from the foregoing, the specified condition for choosing between the 1944-bit codeword and the new longer codeword 1944×N-bit codeword is dependent on the per-CW parity bits. In this second example, for any Navbits>2592, the PPDU encoding parameter table 800 chooses the new longer codeword 1944×N if

$$( Navbits - {N}_{pld} ) / ⌈ \frac{{N}_{pld}}{1944 * R} ⌉ > N 1 , i . e . , Navbits < {N}_{pld} + ⌈ \frac{{N}_{pld}}{1944 * R} ⌉ * N 1.$$

In this case, the Navbits threshold value N1 is lookup table dependent on the code rate N1(R). Alternatively, the Navbits threshold value N1 is defined as a fixed ratio N1=1944*N*(1−R)*N2, where N2 is fixed ratio. As will be appreciated, the PPDU encoding parameter table 800 may include more than one new LDPC codeword length, in which case there should be defined one threshold for each codeword length.

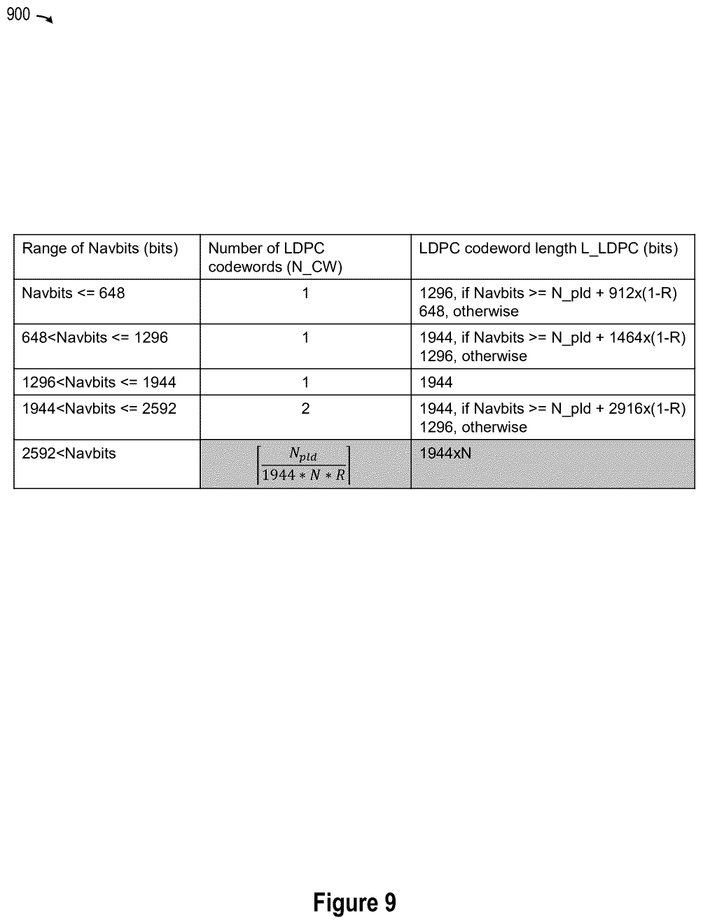

Referring now to FIG. 9, there is depicted a PPDU encoding parameter table 900 in accordance with selected fifth embodiments of the present disclosure. As depicted, the PPDU encoding parameter table 900 specifies a fifth set of LDPC encoding parameters including a Navbits threshold (e.g., 2592 bits) for a maximum LDPC codeword size of N×1944 bits. In the depicted example, the PPDU encoding parameter table 900 is generated by modifying the 802.11n PPDU encoding parameter table 400 to keep the LDPC codeword length (L_LDPC) entries up to the 2592 bit range of Navbits, but to add a longer 1944×N-bit codeword above the 2592 bit range of Navbits (as indicated in gray). As a result, if the number of the available bits Navbits>2592, then the 1944×N-bit codeword is selected. And for longer 1944×N-bit codeword, the number of LDPC codewords N_{CW}=N_{pld}/(1944×N×R).

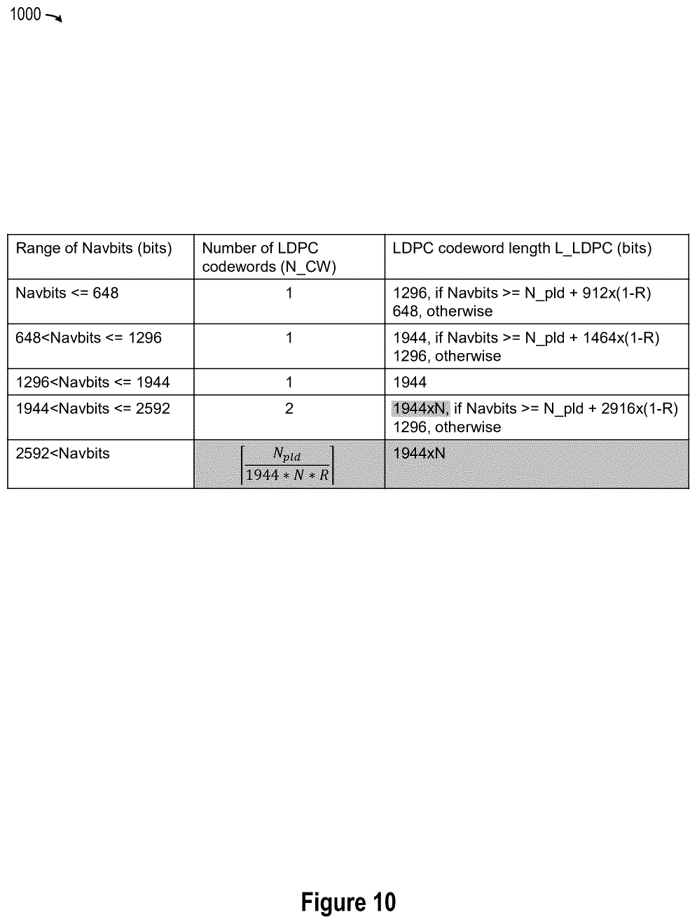

Referring now to FIG. 10, there is depicted a PPDU encoding parameter table 1000 in accordance with selected sixth embodiments of the present disclosure. As depicted, the PPDU encoding parameter table 1000 specifies a sixth set of LDPC encoding parameters including a maximum LDPC codeword size of N×1944 bits that is used for all cases where the number of codewords N_{CW}≥2. In the depicted example, the PPDU encoding parameter table 1000 is generated by modifying the 802.11n PPDU encoding parameter table 400 to keep the LDPC codeword length (L_LDPC) entries up to the 2592 bit range of Navbits, but to replace the 1944 bit codeword for all cases that the 1944-bit codeword was used with N_CW≥2 (as indicated in gray). As a result, if the number of the available bits 1944<Navbits≤2592, then the 1944×N-bit codeword is selected and the number of LDPC codewords N_{CW}=2. And if the number of the available bits Navbits>2592, then the 1944×N-bit codeword is selected and the number of LDPC codewords N_{CW}=N_{pld}/(1944×N×R).

As an alternative, there is depicted below a PPDU encoding parameter table which specifies a set of LDPC encoding parameters including a maximum LDPC codeword size of N×1944 bits that is used for all cases where the number of available bits 1944<Navbits≤2592 if Navbits≥(N_pld+2916×(1−R)) and also for cases where the number of available bits Navbits>2592. In the depicted example, the PPDU encoding parameter table is generated by modifying the 802.11n PPDU encoding parameter table 400 to keep the LDPC codeword length (L_LDPC) entries up to the 2592 bit range of Navbits, but to replace the 1944 bit codeword for all cases that the 1944-bit codeword was used with N_CW≥2 (as indicated in gray). As a result, if the number of the available bits 1944<Navbits≤2592, then the 1944×N-bit codeword is selected if Navbits≥(N_pld+2916×(1−R)) and the number of LDPC codewords N_{CW}=1. But if the number of the available bits 1944<Navbits≤2592 and the number of available Navbits<(N_pld+2916×(1−R)), then the 1296-bit codeword is selected and the number of LDPC codewords N_{CW}=2. And if the number of the available bits Navbits>2592, then the 1944×N-bit codeword is selected and the number of LDPC codewords N_{CW}=N_{pld}/(1944×N×R).

| | Number of | |
|---|---|---|
| | LDPC | |
| Range of Navbits | codewords | LDPC |
| (bits) | (N_CW) | codeword length L_LDPC (bits) |
| Navbits <= 648 | 1 | 1296, if Navbits >= N_pld + |
| | | 912x(1-R) 648, otherwise |
| 648 < Navbits <= | 1 | 1944, if Navbits >= N_pld + |
| 1296 | | 1464x(1-R) 1296, otherwise |
| 1296 < Navbits <= | 1 | 1944 |
| 1944 | | |
| 1944 < Navbits <= | 1 | 1944xN, if Navbits >= N_pld + |
| 2592 | 2 | 2916x(1-R) 1296, otherwise |
| 2592 < Navbits | $⌈ \frac{{N}_{pld}}{1944 * N * R} ⌉$ | 1944xN |

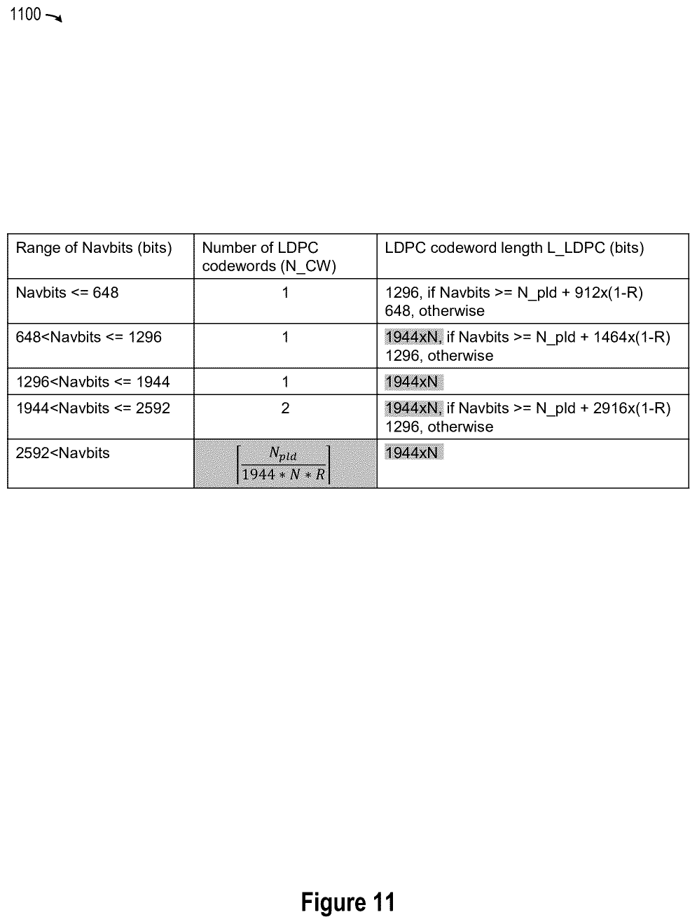

Referring now to FIG. 11, there is depicted a PPDU encoding parameter table 1100 in accordance with selected seventh embodiments of the present disclosure. As depicted, the PPDU encoding parameter table 1100 specifies a seventh set of LDPC encoding parameters including a maximum LDPC codeword size of N×1944 bits that is used for all cases where the 1944-bit codeword was used in the 801.11n standard. In the depicted example, the PPDU encoding parameter table 1200 is generated by modifying the 802.11n PPDU encoding parameter table 400 to keep the LDPC codeword length (L_LDPC) entries up to the 2592 bit range of Navbits, but to replace the 1944 bit codeword for all cases that the 1944-bit codeword was used (as indicated in gray). In addition, if the number of the available bits Navbits>2592, then the number of LDPC codewords N_{CW}=N_{pld}/(1944×N×R).

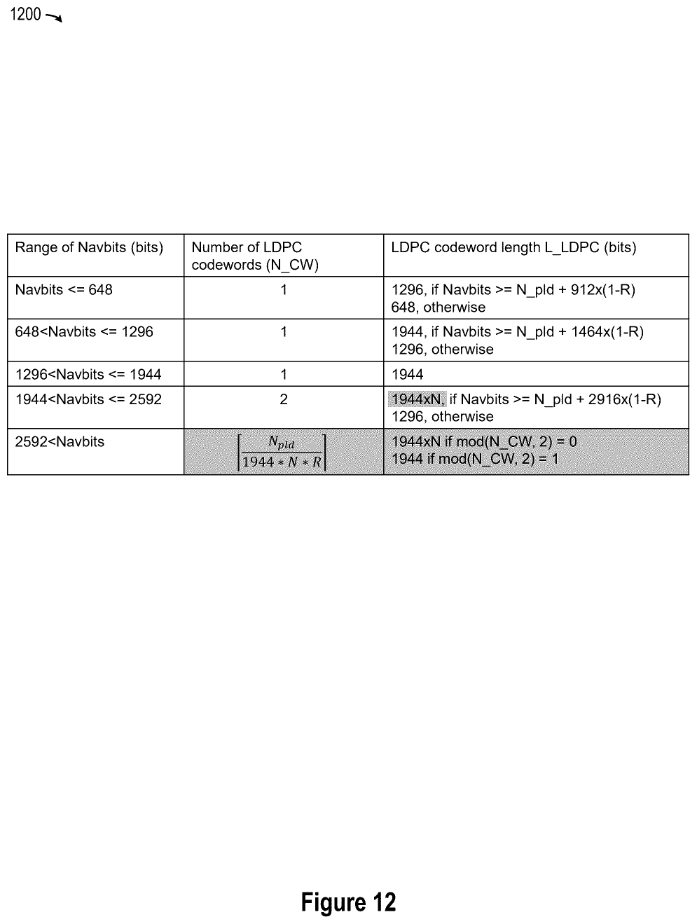

Referring now to FIG. 12, there is depicted a PPDU encoding parameter table 1200 in accordance with selected eighth embodiments of the present disclosure. As depicted, the PPDU encoding parameter table 1200 specifies an eighth set of LDPC encoding parameters including a maximum LDPC codeword size of N×1944 bits that is used for all cases where the number of 1944 codewords N_{CW} is even. In the depicted example, the PPDU encoding parameter table 1200 is generated by modifying the 802.11n PPDU encoding parameter table 400 to keep the LDPC codeword length (L_LDPC) entries up to the 2592 bit range of Navbits, but to replace the 1944 bit codeword for all cases that the 1944-bit codeword was used with there being an even number of 1944 codewords N_CW (as indicated in gray). This is indicated with the L_LDPC computation to choose the 1944×N-bit codeword if mod (N_CW, 2)=0, and to choose the 1944-bit codeword if mod (N_CW, 2)=1. In addition, if the number of the available bits Navbits>2592, then the final number of LDPC codewords N_{CW}=N_{pld}/(1944×N×R).

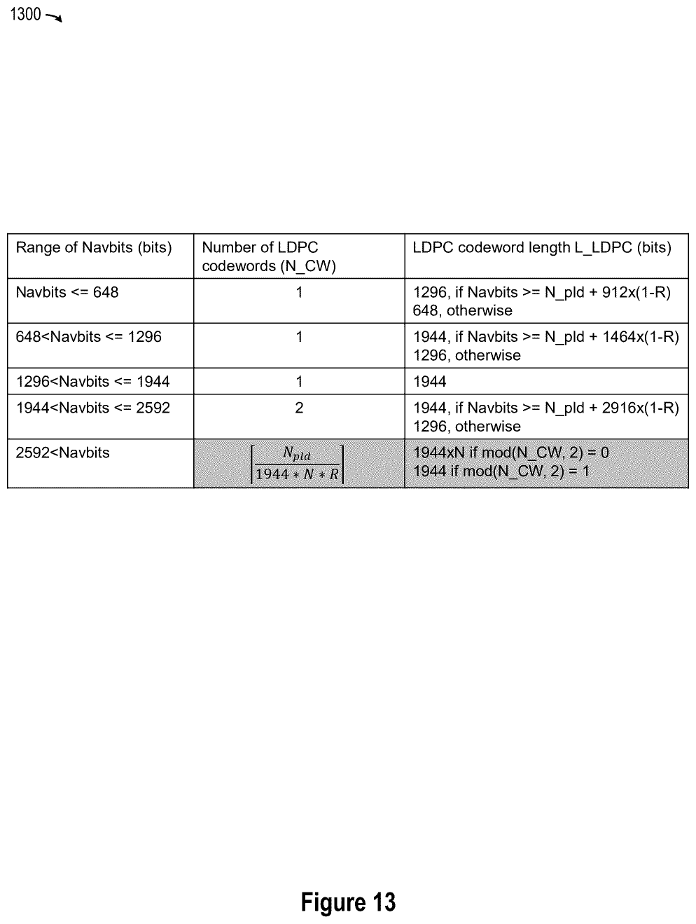

Referring now to FIG. 13, there is depicted a PPDU encoding parameter table 1300 in accordance with selected ninth embodiments of the present disclosure. As depicted, the PPDU encoding parameter table 1300 specifies a ninth set of LDPC encoding parameters including a maximum LDPC codeword size of N×1944 bits that is used only when the number of 1944 codewords N_{CW} is even and the number of available Navbits exceeds a threshold value of 2592 bits. In the depicted example, the PPDU encoding parameter table 1300 is generated by modifying the 802.11n PPDU encoding parameter table 400 to keep the LDPC codeword length (L_LDPC) entries up to the 2592 bit range of Navbits, but to add a longer 1944×N-bit codeword above the 2592 bit range of Navbits for all cases when there is an even number of codewords N_CW (as indicated in gray). This is indicated with the L_LDPC computation to choose the 1944×N-bit codeword if mod (N_CW, 2)=0, and to choose the 1944-bit codeword if mod (N_CW, 2)=1. In addition, if the number of the available bits Navbits>2592, then the final number of LDPC codewords N_{CW}=N_{pld}/(1944×N×R).

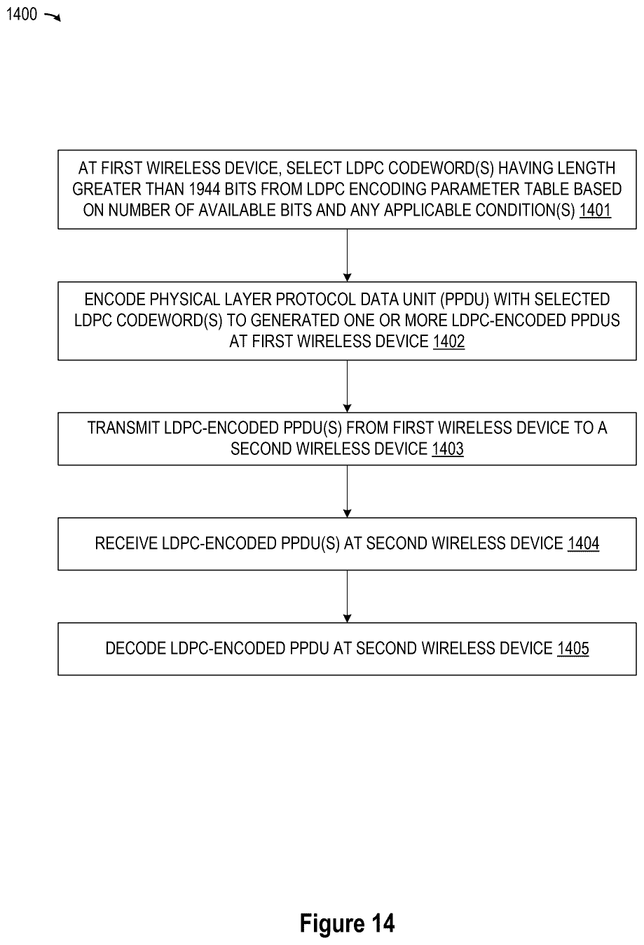

To provide additional details for an improved understanding of selected embodiments of the present disclosure, reference is now made to FIG. 14 which depicts an exemplary logic flow diagram 1400 to illustrate the operation of a wireless communication station (STA) device which uses LDPC codewords having codeword lengths greater than 1944 bits to perform LDPC encoding operations on one or more PPDUs. At step 1401, a first wireless device selects one or more low-density parity-check (LDPC) codewords having a length that is greater than 1944 bits from an LDCP encoding parameter table based on the number of available bits any applicable conditions. At step 1402, the first wireless device encodes a Physical Layer Protocol Data Units (PPDU) with the selected LDPC codeword(s) to generate one or more LDPC-encoded PPDUs. At step 1403, the first wireless device transmits the one or more LDPC-encoded PPDUs to a second wireless device. At step 1404, the second wireless device receives the one or more LDPC-encoded PPDUs. At step 1405, the second wireless device decodes the one or more LDPC-encoded PPDUs. In selected embodiments, the first wireless device includes a wireless access point (AP), and the second wireless device includes a non-AP wireless station (STA) device. In selected embodiments, the first wireless device is compatible with an Institute of Electrical and Electronics Engineers (IEEE) 802.11 protocol. In selected embodiments, the first wireless device is a component of a multi-link device (MLD). The first wireless device and/or the second wireless device may be the same as or similar to an embodiment of the AP/transmitter STA 11 depicted in FIG. 1, the non-AP/receiver STA 21, 31, 41 depicted in FIG. 1, the APs 202, 204 depicted in FIG. 2, the STAs 207, 208 depicted in FIG. 2, and/or the wireless device 300 depicted in FIG. 3.

Although the operations of the method(s) herein are shown and described in a particular order, the order of the operations of each method may be altered so that certain operations may be performed in an inverse order or so that certain operations may be performed, at least in part, concurrently with other operations. In another embodiment, instructions or sub-operations of distinct operations may be implemented in an intermittent and/or alternating manner. It should also be noted that at least some of the operations for the methods described herein may be implemented using software instructions stored on a computer useable storage medium for execution by a computer. As an example, an embodiment of a computer program product includes a computer useable storage medium to store a computer readable program. The computer-useable or computer-readable storage medium can be an electronic, magnetic, optical, electromagnetic, infrared, or semiconductor system (or apparatus or device). Examples of non-transitory computer-useable and computer-readable storage media include a semiconductor or solid-state memory, magnetic tape, a removable computer diskette, a random-access memory (RAM), a read-only memory (ROM), a rigid magnetic disk, and an optical disk. Current examples of optical disks include a compact disk with read only memory (CD-ROM), a compact disk with read/write (CD-R/W), and a digital video disk (DVD). Alternatively, embodiments of the invention may be implemented entirely in hardware or in an implementation containing both hardware and software elements. In embodiments which use software, the software may include but is not limited to firmware, resident software, microcode, etc.

By now it should be appreciated that there has been provided a wireless communication apparatus, method, and system for generating and encoding Low-Density Parity Check (LDPC) Physical Layer Protocol Data Units (PPDUs) in accordance with an Ultra-High Reliability (UHR) communication protocol and other next-generation wireless protocols. In the disclosed methodology, a first wireless communication station computes a number of available bits (Navbits) in a minimum number of orthogonal frequency division multiplexing (OFDM) symbols in which a data field of a packet fits. In addition, the first wireless communication station selects, from an encoding parameter table having a plurality of LDPC codeword lengths, a first LDPC codeword length of N×1944 bits and an integer number of LDPC codewords (N_{CW}) based on comparing the number of available bits (Navbits) to one or more Navbits threshold values and/or selection conditions for choosing the first LDPC codeword length of N×1944 bits, where N is an integer that is greater than or equal to 2. In addition, the first wireless communication station selects, encodes a plurality of bits to create LDPC encoded data bits based on the first LDPC codeword length and the integer number of LDPC codewords (N_{CW}). In addition, the first wireless communication station selects forms a physical protocol data unit (PPDU) using the LDPC encoded data bits. In addition, the first wireless communication station transmits a frame that contains the PPDU to a second wireless communication station. In selected embodiments, the first LDPC codeword length is selected by using the number of available bits (Navbits) to access the encoding parameter table to select the first LDPC codeword length of N×1944 bits if the number of available bits (Navbits) exceeds a first Navbits threshold value, and wherein the integer number of LDPC codewords (N_{CW}) is computed as a ceiling function of N_{pld}/(1944×R×N), where N_{pld} is a number of bits in the data field and a service field of the PPDU, where R is a coding rate, where N is the integer that is greater than or equal to 2, where R is a coding rate. In selected embodiments, the first Navbits threshold value is an integer value N1 that is greater than 648. In other selected embodiments, the encoding parameter table does not include an LDPC codeword length of 1944 bits. In selected embodiments, the first Navbits threshold value is an integer value N1 that is greater than 2592. In other such embodiments, the integer value N1 is 1944×N. In other such embodiments, the integer value N1 is 3888. In other selected embodiments, the encoding parameter table includes an LDPC codeword length of 1944 bits for specified selection conditions when Navbits>648. In selected embodiments, the LDPC codeword length of 1944×N bits is selected on a condition that the first wireless communication station chooses to use a 1944×N-bit codeword. In selected embodiments, the first Navbits threshold value is computed as N_{pld}+((N_{pld}/1944×N×R)×N1), where N1 is a ratio between 0 and 1. In other selected embodiments, the first Navbits threshold value is computed as N_{pld}+((N_{pld}/1944×R)×N1), where N1 is a ratio between 0 and 1. In selected embodiments, the first LDPC codeword length is selected by using the number of available bits (Navbits) to access the encoding parameter table to select the first LDPC codeword length of 1944×N bits if the number of available bits (Navbits) (1) meets or exceeds a first Navbits threshold value computed as N_{pld}+(2916×(1−R)), where N_{pld} is a number of bits in the data field and a service field of the PPDU, and where R is a coding rate, or (2) exceeds a second Navbits threshold value that is 2592. In other selected embodiments, the first LDPC codeword length is selected by using the number of available bits (Navbits) to access the encoding parameter table to select the first LDPC codeword length of 1944×N bits if the number of available bits (Navbits) (1) meets or exceeds a first Navbits threshold value computed as N_{pld}+(1464×(1−R)) where 648<Navbits≤1296, where N_{pld} is a number of bits in the data field and a service field of the PPDU, and where R is a coding rate, or (2) exceeds a second Navbits threshold value that is 1296, where 1296<Navbits≤1944, or (3) meets or exceeds a third Navbits threshold value computed as N_{pld}+(2916×(1−R)), where 1944<Navbits≤2592, or (4) exceeds a fourth Navbits threshold value that is 2592. In other selected embodiments, the first LDPC codeword length is selected by using the number of available bits (Navbits) to access the encoding parameter table to select the first LDPC codeword length of 1944×N bits if the number of available bits (Navbits) (1) meets or exceeds a first Navbits threshold value computed as N_{pld}+(2916×(1−R)), where 1944<Navbits≤2592, where N_{pld} is a number of bits in the data field and a service field of the PPDU, and where R is a coding rate, or (2) exceeds a second Navbits threshold value that is 2592 and there is an even integer number of 1944-bit LDPC codewords (N_{CW}). In other selected embodiments, the first Navbits threshold value is computed as N_{pld}+ ((N_{pld}/1944×R)×N1), where N1 is an integer value that is greater than 2592. In selected embodiments, the first LDPC codeword length is selected by using the number of available bits (Navbits) to access the encoding parameter table to select the first LDPC codeword length of N×1944 bits if the number of available bits (Navbits) exceeds a first Navbits threshold value that is 2592 and there is an even number of integer number of LDPC codewords (N_{CW}).

In another form, there is provided a wireless device, system, and associated method of operation. As disclosed, the wireless device includes a processor that is configured to generate a Physical Layer Protocol Data Unit (PPDU) to include LDPC encoded data bits and to transmit the PPDU in a frame. In particular, the processor is configured to compute a number of available bits (Navbits) in a minimum number of orthogonal frequency division multiplexing (OFDM) symbols in which a data field of a packet fits. In addition, the processor is configured to select, from an encoding parameter table having a plurality of LDPC codeword lengths, a first Low-Density Parity Check (LDPC) codeword length of N×1944 bits based on comparing the number of available bits (Navbits) to one or more selection conditions for choosing the first LDPC codeword length of N×1944 bits, where N is an integer that is greater than or equal to 2. The processor is also configured to encode, based on the first LDPC codeword length, a plurality of bits to create LDPC encoded data bits. In addition, the processor is configured to form a physical protocol data unit (PPDU) using the LDPC encoded data bits. The processor is also configured to transmit to a second wireless device a frame that contains the PPDU. In selected embodiments, the processor is configured to select the first LDPC codeword length by comparing the number of available bits (Navbits) to a first Navbits threshold value that is greater than 648. In other selected embodiments, the encoding parameter table does not include an LDPC codeword length of 1944 bits. In other selected embodiments, the processor is configured to select the first LDPC codeword length by comparing the number of available bits (Navbits) to a first Navbits threshold value that is greater than 2592. In other selected embodiments, the processor is configured to select the first LDPC codeword length by comparing the number of available bits (Navbits) to a first Navbits threshold value that is 1944×N.

In yet another form, there is provided a system, device, and associated method of operation for transmitting an encoded message from a first station (STA) device to a second STA device in a wireless personal area network in accordance with IEEE 802.11 protocol. In the disclosed system, the first STA device generates a set of message-data-bits. In addition, the first STA device computes a number of available bits (Navbits) in a minimum number of orthogonal frequency division multiplexing (OFDM) symbols in which a data field of a packet fits. In addition, the first STA device selects, from an encoding parameter table having a plurality of LDPC codeword lengths, a first Low-Density Parity Check (LDPC) codeword length of N×1944 bits and an integer number of LDPC codewords (N_{CW}) by using the number of available bits (Navbits) to access the encoding parameter table to select the first LDPC codeword length of N×1944 bits if the number of available bits (Navbits) exceeds a first Navbits threshold value. In addition, the first STA device computes the integer number of LDPC codewords (N_{CW}) as a ceiling function of N_{pld}/(1944×R×N), where N_{pld} is a number of bits in the data field and a service field of the PPDU, where R is a coding rate, where N is the integer that is greater than or equal to 2, where R is a coding rate. In addition, the first STA device encodes the set of message-data-bits to create LDPC encoded data bits based on the first LDPC codeword length and the integer number of LDPC codewords (N_{CW}). In addition, the first STA device forms a physical protocol data unit (PPDU) using the LDPC encoded data bits. In addition, the first STA device selects transmits a frame that contains the PPDU from the first STA device to the second STA device.

Although the described exemplary embodiments disclosed herein are directed to a wireless communication station (STA) devices which encode PPDUs with LDPC codewords that are longer than 1944 bits in selected 802.11-compliant wireless connectivity applications and methods for operating same, the present invention is not necessarily limited to the example embodiments which illustrate inventive aspects of the present invention that are applicable to a wide variety of circuit designs and operations. Thus, the particular embodiments disclosed above are illustrative only and should not be taken as limitations upon the present invention, as the invention may be modified and practiced in different but equivalent manners apparent to those skilled in the art having the benefit of the teachings herein. Accordingly, the identification of the circuit design and configurations provided herein is merely by way of illustration and not limitation and other circuit arrangements may be used in order to implement LDPC encoding of PPDUs. Accordingly, the foregoing description is not intended to limit the invention to the particular form set forth, but on the contrary, is intended to cover such alternatives, modifications and equivalents as may be included within the spirit and scope of the invention as defined by the appended claims so that those skilled in the art should understand that they can make various changes, substitutions and alterations without departing from the spirit and scope of the invention in its broadest form.

At least some of the various blocks, operations, and techniques described above may be implemented utilizing hardware, a processor executing firmware instructions, a processor executing software instructions, or any combination thereof. When implemented utilizing a processor executing software or firmware instructions, the software or firmware instructions may be stored in any computer readable memory such as on a magnetic disk, an optical disk, or other storage medium, in a RAM or ROM or flash memory, processor, hard disk drive, optical disk drive, tape drive, etc. The software or firmware instructions may include machine readable instructions that, when executed by one or more processors, cause the one or more processors to perform various acts. When implemented in hardware, the hardware may comprise one or more of discrete components, an integrated circuit, an application-specific integrated circuit (ASIC), a programmable logic device (PLD), etc.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

What is claimed is:

1. A wireless communication method, comprising:
computing, at a wireless communication station, a number of available bits (Navbits) in a minimum number of orthogonal frequency division multiplexing (OFDM) symbols in which a data field of a packet fits;
selecting, from an encoding parameter table comprising a plurality of LDPC codeword lengths, a first Low-Density Parity Check (LDPC) codeword length of N×1944 bits and an integer number of LDPC codewords (N_{CW}) based on comparing the number of available bits (Navbits) to one or more Navbits threshold values and/or one or more selection conditions for choosing the first LDPC codeword length of N×1944 bits, where N is an integer that is greater than or equal to 2;
encoding, at the wireless communication station, based on the first LDPC codeword length and the integer number of LDPC codewords (N_{CW}), a plurality of bits to create LDPC encoded data bits;
forming, at the wireless communication station, a physical protocol data unit (PPDU) using the LDPC encoded data bits; and
transmitting, by the first wireless communication station a frame that contains the PPDU.

2. The wireless communication method of claim 1, wherein selecting the first LDPC codeword length comprises using the number of available bits (Navbits) to access the encoding parameter table to select the first LDPC codeword length of N×1944 bits if the number of available bits (Navbits) exceeds a first Navbits threshold value, and wherein the integer number of LDPC codewords (N_{CW}) is computed as a ceiling function of N_{pld}/(1944×R×N), where N_{pld} is a number of bits in the data field and a service field of the PPDU, where R is a coding rate, where N is the integer that is greater than or equal to 2, where R is a coding rate.

3. The wireless communication method of claim 2, wherein the first Navbits threshold value is an integer value N1 that is greater than 648.

4. The wireless communication method of claim 2, wherein the encoding parameter table does not include an LDPC codeword length of 1944 bits.

5. The wireless communication method of claim 2, wherein the first Navbits threshold value is an integer value N1 that is greater than 2592.

6. The wireless communication method of claim 5, wherein N1 is 1944×N.

7. The wireless communication method of claim 6, wherein N1 is 3888.

8. The wireless communication method of claim 2, wherein the encoding parameter table includes an LDPC codeword length of 1944 bits when Navbits>648.

9. The wireless communication method of claim 2, wherein the LDPC codeword length of 1944×N bits is selected on a condition that the first wireless communication station chooses to use a 1944×N-bit codeword.

10. The wireless communication method of claim 2, wherein the first Navbits threshold value is computed as N_{pld}+((N_{pld}/1944×N×R)×N1), where N1 is a ratio between 0 and 1.

11. The wireless communication method of claim 2, wherein the first Navbits threshold value is computed as N_{pld}+((N_{pld}/1944×R)×N1), where N1 is a ratio between 0 and 1.

12. The wireless communication method of claim 1, wherein selecting the first LDPC codeword length comprises accessing the encoding parameter table to select the first LDPC codeword length of N×1944 bits if the number of available bits (Navbits):
(1) meets or exceeds a first Navbits threshold value computed as N_{pld}+(2916×(1−R)), where N_{pld} is a number of bits in the data field and a service field of the PPDU, and where R is a coding rate, or
(2) exceeds a second Navbits threshold value that is 2592.

13. The wireless communication method of claim 1, wherein selecting the first LDPC codeword length comprises accessing the encoding parameter table to select the first LDPC codeword length of N×1944 bits if the number of available bits (Navbits):
(1) meets or exceeds a first Navbits threshold value computed as N_{pld}+(1464×(1−R)) where 648<Navbits≤1296, where N_{pld} is a number of bits in the data field and a service field of the PPDU, and where R is a coding rate, or
(2) exceeds a second Navbits threshold value that is 1296, where 1296<Navbits≤1944, or
(3) meets or exceeds a third Navbits threshold value computed as N_{pld}+(2916×(1−R)), where 1944<Navbits≤2592, or
(4) exceeds a fourth Navbits threshold value that is 2592.

14. The wireless communication method of claim 1, wherein selecting the first LDPC codeword length comprises accessing the encoding parameter table to select the first LDPC codeword length of N×1944 bits if the number of available bits (Navbits):
(1) meets or exceeds a first Navbits threshold value computed as N_{pld}+(2916×(1−R)), where 1944<Navbits≤2592, where N_{pld} is a number of bits in the data field and a service field of the PPDU, and where R is a coding rate, or
(2) exceeds a second Navbits threshold value that is 2592 and there is an even number of integer number of 1944 LDPC codewords (N_{CW}).

15. The wireless communication method of claim 1, wherein selecting the first LDPC codeword length comprises accessing the encoding parameter table to select the first LDPC codeword length of N×1944 bits if the number of available bits (Navbits) exceeds a first Navbits threshold value that is 2592 and there is an even integer number of 1944-bit LDPC codewords (N_{CW}).

16. The wireless communication method of claim 1, wherein selecting the first LDPC codeword length of N×1944 bits comprises comparing the number of available bits (Navbits) to one or more Navbits threshold values and/or one or more selection conditions.

17. A wireless device, comprising:
a processor configured to:
compute a number of available bits (Navbits) in a minimum number of orthogonal frequency division multiplexing (OFDM) symbols in which a data field of a packet fits;
select, from an encoding parameter table comprising a plurality of LDPC codeword lengths, a first Low-Density Parity Check (LDPC) codeword length of N×1944 bits based on comparing the number of available bits (Navbits) to one or more selection conditions for choosing the first LDPC codeword length of N×1944 bits, where N is an integer that is greater than or equal to 2;
encode, based on the first LDPC codeword length, a plurality of bits to create LDPC encoded data bits;
form a physical protocol data unit (PPDU) using the LDPC encoded data bits; and
transmit a frame that contains the PPDU.

18. The wireless device of claim 17, wherein the processor is configured to select the first LDPC codeword length by comparing the number of available bits (Navbits) to a first Navbits threshold value that is greater than 648.

19. The wireless device of claim 17, wherein the encoding parameter table does not include an LDPC codeword length of 1944 bits.

20. The wireless device of claim 17, wherein the processor is configured to select the first LDPC codeword length by comparing the number of available bits (Navbits) to a first Navbits threshold value that is greater than 2592.

21. The wireless device of claim 17, wherein the processor is configured to select the first LDPC codeword length by comparing the number of available bits (Navbits) to a first Navbits threshold value that is 1944×N.

22. A system for transmitting an encoded message from a first station (STA) device to a second STA device in a wireless personal area network in accordance with IEEE 802.11 protocol, comprising:
generating, at the first STA device, a set of message-data-bits;
computing, at the first STA device, a number of available bits (Navbits) in a minimum number of orthogonal frequency division multiplexing (OFDM) symbols in which a data field of a packet fits;
selecting, from an encoding parameter table comprising a plurality of LDPC codeword lengths, a first Low-Density Parity Check (LDPC) codeword length of N×1944 bits and an integer number of LDPC codewords (N_{CW}) by using the number of available bits (Navbits) to access the encoding parameter table to select the first LDPC codeword length of N×1944 bits if the number of available bits (Navbits) exceeds a first Navbits threshold value, and wherein the integer number of LDPC codewords (N_{CW}) is computed as a ceiling function of N_{pld}/(1944×R×N), where N_{pld} is a number of bits in the data field and a service field of the PPDU, where R is a coding rate, where N is the integer that is greater than or equal to 2, where R is a coding rate;
encoding, at the first STA device, the set of message-data-bits to create LDPC encoded data bits based on the first LDPC codeword length and the integer number of LDPC codewords (N_{CW});
forming, at the first STA device, a physical protocol data unit (PPDU) using the LDPC encoded data bits; and
transmitting a frame that contains the PPDU from the first STA device to the second STA device.
